(19) United States
(12) Patent Application Publication
(10) Pub. No.: US 2026/0096126 A1
(43) Pub. Date: Apr. 2, 2026

(54) SEMICONDUCTOR DEVICE AND METHOD FOR MANUFACTURING SEMICONDUCTOR DEVICE

(71) Applicant: SUMITOMO ELECTRIC DEVICE INNOVATIONS, INC., Kanagawa (JP)

(72) Inventor: Kenta SUGAWARA, Kanagawa (JP)

(21) Appl. No.: 19/325,881

(22) Filed: Sep. 11, 2025

(30) Foreign Application Priority Data
Sep. 27, 2024 (JP) 2024-168312

(51) Int. Cl. H10D 30/47; H10D 30/01; H10D 62/10; H10D 62/60; H10D 62/85; H10D 64/23; H10D 64/27; H10D 64/62; H10D 64/64

(52) U.S. Cl. CPC H10D 30/471; H10D 30/015; H10D 62/102; H10D 62/60; H10D 62/8503; H10D 64/254; H10D 64/411; H10D 64/62; H10D 64/64

(57) ABSTRACT

A semiconductor device includes a substrate having a first surface, and a second surface opposite to the first surface, a first nitride semiconductor layer having a third surface in contact with the second surface, and a fourth surface opposite to the third surface, the fourth surface having a recess, a second nitride semiconductor layer provided inside the recess, a first metal layer provided on the second nitride semiconductor layer, a through hole penetrating the substrate, the first nitride semiconductor layer, and the second nitride semiconductor layer, and reaching the first metal layer, and a second metal layer in contact with the first metal layer and covering the first surface and an inner wall surface of the through hole. The first metal layer includes cobalt, and the second nitride semiconductor layer includes impurity atoms at a concentration of 1.0×10¹⁸ cm⁻³ or higher.

### CROSS-REFERENCE TO RELATED APPLICATIONS

This application is based upon and claims priority to Japanese Patent Application No. 2024-168312, filed on Sep. 27, 2024, the entire contents of which are incorporated herein by reference.

### TECHNICAL FIELD

The present disclosure relates to semiconductor devices, and methods for manufacturing the semiconductor devices.

### BACKGROUND

There is a known semiconductor device having a metal layer in ohmic contact with a semiconductor layer that includes carriers at a high concentration. The metal layer is formed as an etching stopper on the semiconductor layer. A through hole reaching the etching stopper is formed in the semiconductor layer, and an electrode in contact with the etching stopper is formed inside the through hole.

Japanese Laid-Open Patent Publication No. 2024-092747 is an example of the related art.

### SUMMARY

According to one aspect of the present disclosure, a semiconductor device includes a substrate having a first surface, and a second surface opposite to the first surface; a first nitride semiconductor layer having a third surface in contact with the second surface, and a fourth surface opposite to the third surface, the fourth surface having a recess; a second nitride semiconductor layer provided inside the recess; a first metal layer provided on the second nitride semiconductor layer; a through hole penetrating the substrate, the first nitride semiconductor layer, and the second nitride semiconductor layer, and reaching the first metal layer; and a second metal layer in contact with the first metal layer and covering the first surface and an inner wall surface of the through hole, wherein the first metal layer includes cobalt, and the second nitride semiconductor layer includes impurity atoms at a concentration of 1.0×10¹⁸ cm⁻³ or higher.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a diagram illustrating a layout of a gate electrode, a source interconnect, and a drain interconnect of a semiconductor device according to a first embodiment;

FIG. 2 is a cross sectional view illustrating the semiconductor device according to the first embodiment;

FIG. 3 is a diagram illustrating a band structure of a semiconductor layer (regrowth layer);

FIG. 4 is a cross sectional view (part 1) illustrating a first example of a method for manufacturing the semiconductor device according to the first embodiment;

FIG. 5 is a cross sectional view (part 2) illustrating the first example of the method for manufacturing the semiconductor device according to the first embodiment;

FIG. 6 is a cross sectional view (part 3) illustrating the first example of the method for manufacturing the semiconductor device according to the first embodiment;

FIG. 7 is a cross sectional view (part 4) illustrating the first example of the method for manufacturing the semiconductor device according to the first embodiment;

FIG. 8 is a cross sectional view (part 5) illustrating the first example of the method for manufacturing the semiconductor device according to the first embodiment;

FIG. 9 is a cross sectional view (part 6) illustrating the first example of the method for manufacturing the semiconductor device according to the first embodiment;

FIG. 10 is a cross sectional view (part 7) illustrating the first example of the method for manufacturing the semiconductor device according to the first embodiment;

FIG. 11 is a cross sectional view (part 8) illustrating the first example of the method for manufacturing the semiconductor device according to the first embodiment;

FIG. 12 is a cross sectional view (part 9) illustrating the first example of the method for manufacturing the semiconductor device according to the first embodiment;

FIG. 13 is a cross sectional view (part 10) illustrating the first example of the method for manufacturing the semiconductor device according to the first embodiment;

FIG. 14 is a cross sectional view (part 11) illustrating the first example of the method for manufacturing the semiconductor device according to the first embodiment;

FIG. 15 is a diagram illustrating an example of a change in temperature when forming a metal layer;

FIG. 16 is a cross sectional view (part 1) illustrating a second example of the method for manufacturing the semiconductor device according to the first embodiment;

FIG. 17 is a cross sectional view (part 2) illustrating the second example of the method for manufacturing the semiconductor device according to the first embodiment;

FIG. 18 is a cross sectional view (part 3) illustrating the second example of the method for manufacturing the semiconductor device according to the first embodiment;

FIG. 19 is a diagram illustrating another example of the change in temperature when forming the metal layer;

FIG. 20 is a cross sectional view illustrating the semiconductor device according to a second embodiment;

FIG. 21 is a cross sectional view (part 1) illustrating the method for manufacturing the semiconductor device according to the second embodiment;

FIG. 22 is a cross sectional view (part 2) illustrating the method for manufacturing the semiconductor device according to the second embodiment;

FIG. 23 is a cross sectional view (part 3) illustrating the method for manufacturing the semiconductor device according to the second embodiment;

FIG. 24 is a cross sectional view (part 4) illustrating the method for manufacturing the semiconductor device according to the second embodiment;

FIG. 25 is a cross sectional view (part 5) illustrating the method for manufacturing the semiconductor device according to the second embodiment;

FIG. 26 is a cross sectional view (part 6) illustrating the method for manufacturing the semiconductor device according to the second embodiment; and

FIG. 27 is a cross sectional view (part 7) illustrating the method for manufacturing the semiconductor device according to the second embodiment.

### DETAILED DESCRIPTION

In the known semiconductor device, a contact resistance between the metal layer and the semiconductor layer may become high, thereby deteriorating a yield of the semiconductor device.

One object according to an aspect of the present disclosure is to provide a semiconductor device and a method for manufacturing the semiconductor device which can improve the yield.

According to the present disclosure, it is possible to improve the yield of the semiconductor device.

First, embodiments of the present disclosure will be described with reference to the drawings.
[1] A semiconductor device according to an aspect of the present disclosure includes a substrate having a first surface, and a second surface opposite to the first surface; a first nitride semiconductor layer having a third surface in contact with the second surface, and a fourth surface opposite to the third surface, the fourth surface having a recess; a second nitride semiconductor layer provided inside the recess; a first metal layer provided on the second nitride semiconductor layer; a through hole penetrating the substrate, the first nitride semiconductor layer, and the second nitride semiconductor layer, and reaching the first metal layer; and a second metal layer in contact with the first metal layer and covering the first surface and an inner wall surface of the through hole, wherein the first metal layer includes cobalt, and the second nitride semiconductor layer includes impurity atoms at a concentration of 1.0×10¹⁸ cm⁻³ or higher.

The second nitride semiconductor layer is formed inside the recess formed in the fourth surface of the first nitride semiconductor layer, and the second nitride semiconductor layer includes impurity atoms at the concentration of 1.0×10¹⁸ cm⁻³ or higher. For this reason, an ohmic contact is obtained between the second nitride semiconductor layer and the first metal layer. In addition, the first metal layer including cobalt is highly resistant to substances that may come into contact with the first metal layer between the formation of the through hole and the formation of the second metal layer. Accordingly, the semiconductor device has a good stability of an electrical resistance between the second metal layer and the first nitride semiconductor layer, and a yield of the semiconductor device can be improved.
[2] The semiconductor device according to [1] may further include a third metal layer covering the first metal layer, wherein an electrical resistance of the third metal layer is lower than an electrical resistance of the first metal layer. In this case, an electrical resistance of a source electrode including the first metal layer and the third metal layer can easily be reduced.
[3] In the semiconductor device according to [2], the third metal layer may include at least one kind of material selected from a group consisting of gold, copper, and aluminum. In this case, an electrical resistance of the third metal layer can easily be reduced.
[4] In the semiconductor device according to any one of [1] to [3], the second nitride semiconductor layer may be a gallium nitride layer. In this case, a low electrical resistance can easily be obtained for the second nitride semiconductor layer.
[5] In the semiconductor device according to any one of [1] to [4], a Fermi level may be higher than energy at a lower end of a conduction band in the second nitride semiconductor layer. In this case, an ohmic contact can easily be obtained between the second nitride semiconductor layer and the first metal layer.
[6] In the semiconductor device according to any one of [1] to [5], a carrier concentration of the second nitride semiconductor layer may be higher than a carrier concentration of the first nitride semiconductor layer. In this case, an electrical resistance of the second nitride semiconductor layer can easily be reduced.
[7] The semiconductor device according to any one of [1] to [6] may further include a gate electrode in Schottky contact with the first nitride semiconductor layer, wherein the gate electrode includes a fourth metal layer in direct contact with the first nitride semiconductor layer, and the fourth metal layer includes cobalt. In this case, the first metal layer and the fourth metal layer can be formed simultaneously. In addition, because the fourth metal layer includes cobalt, a high Schottky barrier can easily be obtained in the gate electrode.
[8] In the semiconductor device according to [7], the fourth metal layer may include cobalt in an amorphous state. Such a fourth metal layer can make a gate leakage less likely to occur.
[9] In the semiconductor device according to [8], the fourth metal layer may include hydrogen atoms, carbon atoms, nitrogen atoms, and oxygen atoms. In this case, a state of the fourth metal layer can more easily be made amorphous.
[10] A method for manufacturing a semiconductor device according to another embodiment of the present disclosure includes forming a first nitride semiconductor layer on a substrate having a first surface and a second surface opposite to the first surface, the first nitride semiconductor layer having a third surface in contact with the second surface and a fourth surface opposite to the third surface; forming a recess in the fourth surface; forming a second nitride semiconductor layer inside the recess; forming a first metal layer on the second nitride semiconductor layer; forming a through hole penetrating the substrate, the first nitride semiconductor layer, and the second nitride semiconductor layer and reaching the first metal layer; and forming a second metal layer in contact with the first metal layer and covering the first surface and an inner wall surface of the through hole, wherein the first metal layer includes cobalt, and the second nitride semiconductor layer includes impurity atoms at a concentration of 1.0×10¹⁸ cm⁻³ or higher.

The recess is formed in the fourth surface of the first nitride semiconductor layer, the second nitride semiconductor layer is formed inside the recess, and the second nitride semiconductor layer includes impurity atoms at a concentration of 1.0×10¹⁸ cm⁻³ or higher. In addition, the first metal layer including cobalt is highly resistant to substances that may come into contact with the first metal layer between the formation of the through hole and the formation of the second metal layer. Accordingly, the semiconductor device has a good stability of an electrical resistance between the second metal layer and the first nitride semiconductor layer, and a yield of the semiconductor device can be improved.
[11] In the method for manufacturing the semiconductor device according to [10], the forming the first metal layer may include forming a fifth metal layer including cobalt in an amorphous state on the first nitride semiconductor layer and the second nitride semiconductor layer by an atomic layer deposition; and patterning the fifth metal layer, wherein the patterning the fifth metal layer includes forming a fourth metal layer in direct contact with the first nitride semiconductor layer. In this case, the first metal layer and the fourth metal layer can be formed simultaneously.
[12] In the method for manufacturing the semiconductor device according to [11], a source material of the fifth metal layer may include cobalt bisdiisopropylbutanamidinate. In this case, the fifth metal layer in an amorphous state can easily be formed.
[13] In the method for manufacturing the semiconductor device according to [12], the forming the fifth metal layer may include supplying at least one kind of gas selected from a group consisting of hydrogen gas and ammonia gas into a furnace together with the source material. In this case, it is particularly easy to form the fifth metal layer in an amorphous state.
[14] The method for manufacturing the semiconductor device according to any one of [11] to [13] may further include performing a reduction process at a first temperature at which a natural oxide film on a surface of the first nitride semiconductor layer is decomposed, before the forming the fifth metal layer, wherein the fifth metal layer is formed at a second temperature lower than the first temperature. In this case, good Schottky characteristics can easily be obtained between a gate electrode and the first nitride semiconductor layer.
[15] In the method for manufacturing the semiconductor device according to [14], the performing the reduction process and the forming the fifth metal layer may be performed in the same furnace without being exposed to atmosphere. In this case, an exceptionally high level of cleanliness can be achieved on the surface of the first nitride semiconductor layer.
[16] In the method for manufacturing the semiconductor device according to [14], the performing the reduction process and the forming the fifth metal layer may be performed in different furnaces without being exposed to atmosphere. In this case, the temperature inside the furnace in which the reduction process is performed and the temperature inside the furnace in which the fifth metal layer is formed can be controlled independently of each other, and a high throughput can easily be obtained.
[17] In the method for manufacturing the semiconductor device according to any one of [14] to [16], the performing the reduction process may use hydrogen gas and ammonia gas. In this case, oxygen atoms are removed from the natural oxide film by the hydrogen gas, and nitrogen defects in the first nitride semiconductor layer can be compensated for by the ammonia gas.

### Details of Embodiments of Present Disclosure

Hereinafter, embodiments of the present disclosure will be described in detail, but the present disclosure is not limited thereto. In the present specification and the drawings, constituent elements having substantially the same functional configuration are designated by the same reference numerals, and a redundant description thereof may be omitted. In the following description, an XYZ orthogonal coordinate system is used, but the XYZ coordinate system is defined for the sake of convenience of description and does not limit an orientation of a semiconductor device. Further, when viewed from an arbitrary point, the +Z-side may be also be referred to as above, upper side, or up, and the-Z-side may also be referred to as below, lower side, or down.

### First Embodiment

A first embodiment will be described. The first embodiment relates to a semiconductor device including a GaN-based high electron mobility transistor (HEMT).

### Structure of Semiconductor Device

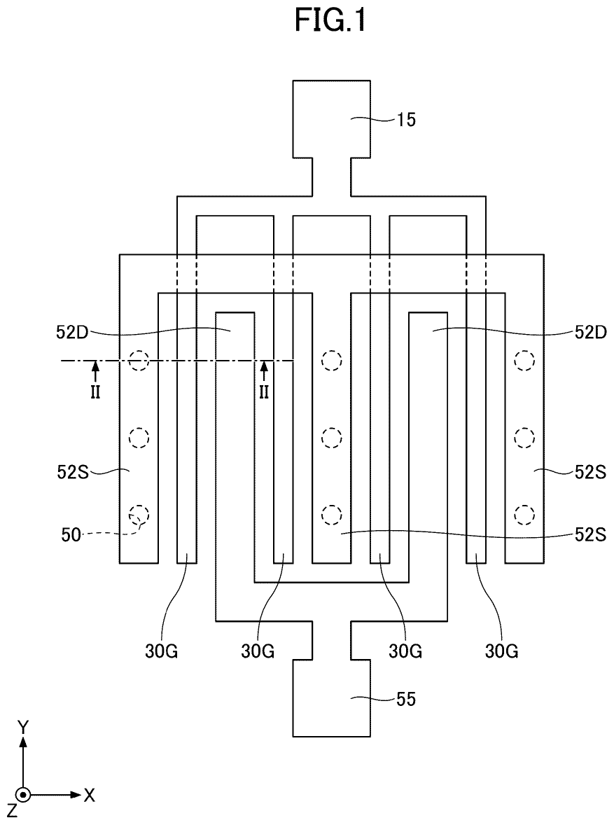

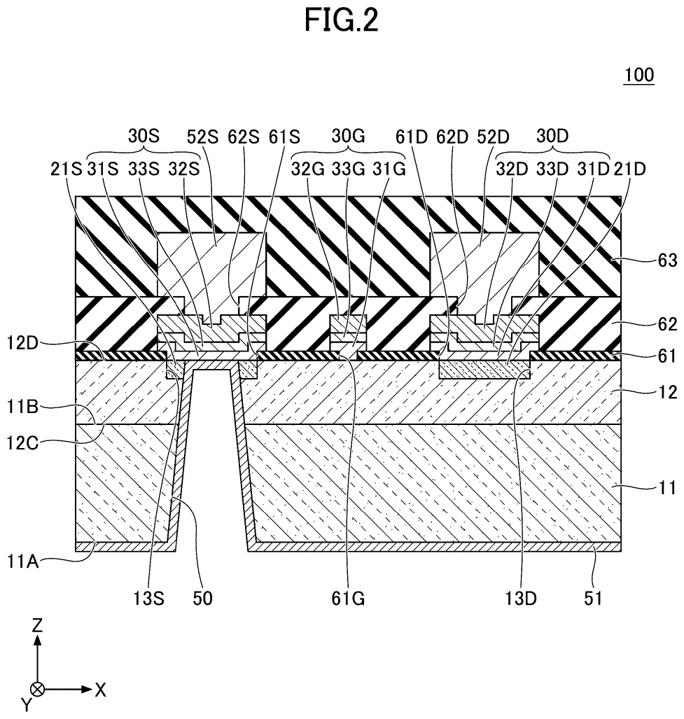

A structure of a semiconductor device according to a first embodiment will be described. FIG. 1 is a diagram illustrating a layout of a gate electrode, a source interconnect, and a drain interconnect of the semiconductor device according to the first embodiment. FIG. 2 is a cross sectional view illustrating the semiconductor device according to the first embodiment. FIG. 2 corresponds to a cross sectional view taken along a line II-II in FIG. 1.

As illustrated in FIG. 1 and FIG. 2, a semiconductor device 100 according to the first embodiment includes a substrate 11, a semiconductor layer 12, a semiconductor layer 21S, a semiconductor layer 21D, a gate electrode 30G, a source electrode 30S, a drain electrode 30D, a source interconnect 52S, a drain interconnect 52D, and a backside electrode 51.

The substrate 11 is a silicon carbide (SiC) substrate, for example. The substrate 11 has a first surface 11A, and a second surface 11A opposite to the first surface 11B. The second surface 11B is located above (on the +Z-side of) the first surface 11A.

The semiconductor layer 12 is provided on the substrate 11. The semiconductor layer 12 has a third surface 12C in contact with the second surface 11B, and a fourth surface 12D opposite to the third surface 12C. The fourth surface 12D is located above (on the +Z-side of) the third surface 12C. The semiconductor layer 12 is a nitride semiconductor layer including gallium (Ga), for example. The nitride semiconductor layer constitutes a portion of a high electron mobility transistor (HEMT), such as an electron transport layer (a channel layer), an electron supply layer (a barrier layer), or the like, and includes a two dimensional electron gas (2 DEG). The semiconductor layer 12 is an example of a first nitride semiconductor layer.

A plurality of recesses 13S and a plurality of recesses 13D are formed in the fourth surface 12D. The recesses 13S and 13D extend parallel to the Y-axis, and are alternately provided along the X-axis. For example, the recesses 13S and 13D reach the electron transport layer (the channel layer). Bottom surfaces of the recesses 13S and 13D may be provided on the electron transport layer.

The semiconductor device 100 includes an insulating film 61. The insulating film 61 covers the fourth surface 12D of the semiconductor layer 12. For example, the insulating film 61 is a nitride film, such as a silicon nitride (SiN) film or the like. A plurality of openings 61S, a plurality of openings 61D, and a plurality of openings 61G are formed in the insulating film 61. The openings 61S, 61D, and 61G penetrate the insulating film 61. The openings 61S, 61D, and 61G extend parallel to the Y-axis. The opening 61S is continuous with the recess 13S, and the opening 61D is continuous with the recess 13D. The opening 61G is provided between the opening 61S and the opening 61D that are adjacent to each other along the X-axis.

The semiconductor layer 21S is provided in the recess 13S, and the semiconductor layer 21D is provided in the recess 13D. A portion of the semiconductor layer 21S may be inside the opening 61S, and a portion of the semiconductor layer 21D may be inside the opening 61D. For example, the semiconductor layers 21S and 21D are gallium nitride (GaN) layers having a conductivity type that is n-type. The semiconductor layers 21S and 21D are regrown layers. Carrier concentrations of the semiconductor layers 21S and 21D are higher than a carrier concentration of the semiconductor layer 12. The semiconductor layers 21S and 21D include n-type impurity atoms at a concentration of 1.0×10¹⁸ cm⁻³ or higher. The semiconductor layers 21S and 21D are degenerate semiconductor layers, for example. The n-type impurity is silicon (Si) or germanium (Ge), for example. The semiconductor layer 21S is an example of a second nitride layer.

The gate electrode 30G extends parallel to the Y-axis. The gate electrode 30G is in Schottky contact with the semiconductor layer 12 through the opening 61G. The gate electrode 30G includes a metal layer 31G, a metal layer 32G, and a metal layer 33G. The metal layer 31G is in direct contact with the semiconductor layer 12. The metal layer 32G covers the metal layer 31G. The metal layer 33G is located between the metal layer 31G and the metal layer 32G. metal layer 31G is on the semiconductor layer 12 and the insulating film 61. The metal layer 33G is provided on the metal layer 31G. The metal layer 32G is provided on the metal layer 33G. The metal layer 31G includes cobalt (Co). The metal layer 31G is a cobalt (Co) layer in an amorphous state, for example. A thickness of the metal layer 31G is greater than or equal to 3 nm and less than or equal to 50 nm, for example. An electrical resistance of the metal layer 32G is lower than an electrical resistance of the metal layer 31G. The metal layer 32G is a gold (Au) layer, for example. A thickness of the metal layer 32G is greater than or equal to 300 nm and less than or equal to 1000 nm, for example. The metal layer 33G increases an adhesion between the metal layer 31G and the metal layer 32G. The metal layer 33G is a titanium (Ti) layer, for example. A thickness of the metal layer 33G is greater than or equal to 2 nm and less than or equal to 20 nm, for example. The metal layer 31G is an example of a fourth metal layer. As illustrated in FIG. 1, the plurality of gate electrodes 30G are connected to a gate common connection part 15.

The source electrode 30S extends parallel to the Y-axis. The source electrode 30S includes a metal layer 31S, a metal layer 32S, and a metal layer 33S. The metal layer 31S is in direct contact with the semiconductor layer 21S. The metal layer 32S covers the metal layer 31S. The metal layer 33S is located between the metal layer 31S and the metal layer 32S. The metal layer 31S is provided on the semiconductor layer 21S and the insulating film 61. The metal layer 33S is provided on the metal layer 31S, The metal layer 32S is provided on the metal layer 33S. The metal layer 31S includes cobalt (Co). The metal layer 31S is a cobalt (Co) layer in an amorphous state, for example. A thickness of the metal layer 31S is greater than or equal to 3 nm and less than or equal to 50 nm, for example. An electrical resistance of the metal layer 32S is lower than an electrical resistance of the metal layer 31S. The metal layer 32S is a gold (Au) layer, for example. A thickness of the metal layer 32S is greater than or equal to 300 nm and less than or equal to 1000 nm, for example. The metal layer 33S increases an adhesion between the metal layer 31S and the metal layer 32S. The metal layer 33S is a titanium (Ti) layer, for example. A thickness of the metal layer 33S is greater than or equal to 2 nm and less than or equal to 20 nm, for example. The metal layer 31S is an example of a first metal layer. The metal layer 32S is an example of a third metal layer.

The drain electrode 30D extends parallel to the Y-axis. The drain electrode 30D includes a metal layer 31D, a metal layer 32D, and a metal layer 33D. The metal layer 31D is in direct contact with the semiconductor layer 21D. The metal layer 32D covers the metal layer 31D. The metal layer 33D is located between the metal layer 31D and the metal layer 32D. The metal layer 31D is provided on the semiconductor layer 21D and the insulating film 61. The metal layer 33D is provided on the metal layer 31D. The metal layer 32D is provided on the metal layer 33D. The metal layer 31D includes cobalt (Co). The metal layer 31D is a cobalt (Co) layer in an amorphous state, for example. A thickness of the metal layer 31D is greater than or equal to 3 nm and less than or equal to 50 nm, for example. An electrical resistance of the metal layer 32D is lower than an electrical resistance of the metal layer 31D. The metal layer 32D is a gold (Au) layer, for example. A thickness of the metal layer 32D is greater than or equal to 300 nm and less than or equal to 1000 nm, for example. The metal layer 33D increases an adhesion between the metal layer 31D and the metal layer 32D. The metal layer 33D is a titanium (Ti) layer, for example. A thickness of the metal layer 33D is greater than or equal to 2 nm and less than or equal to 20 nm, for example.

The semiconductor device 100 includes an insulating film 62. The insulating film 62 covers the source electrode 30S, the drain electrode 30D, the gate electrode 30G, and the insulating film 61. For example, the insulating film 62 is a nitride film, such as a silicon nitride (SiN) film or the like. A plurality of openings 62S and a plurality of openings 62D are formed in the insulating film 62. The opening 62S and 62D extend parallel to the Y-axis. The opening 62S reaches the source electrode 30S, and the opening 62D reaches the drain electrode 30D.

The source interconnect 52S is located above the source electrode 30S. The source interconnect 52S is provided on the insulating film 62. The source interconnect 52S is in contact with the source electrode 30S through the opening 62S. The drain interconnect 52D is located above the drain electrode 30D. The drain interconnect 52D is provided on the insulating film 62. The drain interconnect 52D is in contact with the drain electrode 30D through the opening 62D. Each of the source interconnect 52S and the drain interconnect 52D includes a seed layer, and a plating layer on the seed layer, for example. For example, the seed layer may include a titanium (Ti) layer, and the plating layer may include a gold (Au) layer. As illustrated in FIG. 1, a plurality of drain interconnects 52D may be connected to a drain pad 55, and a plurality of source interconnects 52S may be connected to each other.

The semiconductor device 100 includes an insulating film 63. The insulating film 63 covers the source interconnect 52S, the drain interconnect 52D, and the insulating film 62. For example, the insulating film 63 is a nitride film, such as a silicon nitride (SiN) film or the like.

Although not illustrated, an opening reaching the gate common connection part 15 is formed in the insulating film 62, and a gate pad in contact with the gate common connection part 15 through this opening is formed on the insulating film 62. In addition, an opening reaching the gate pad and an opening reaching the drain pad 55 are formed in the insulating film 63.

A through hole 50 is formed in the substrate 11, the semiconductor layer 12, and the semiconductor layer 21S, so as to penetrate the substrate 11, the semiconductor layer 12, and the semiconductor layer 21S. The through hole 50 reaches the source electrode 30S. At least one through hole 50 is formed with respect to each of the source electrodes 30S. A plurality of through holes 50 may be formed with respect to each of the source electrodes 30S.

The backside electrode 51 is formed on a lower surface of the source electrode 30S, an inner wall surface of the through hole 50, and a lower surface (the first surface 11A) of the substrate 11. The backside electrode 51 is in contact with the source electrode 30S, and covers the first surface 11A and the inner wall surface of the through hole 50. The backside electrode 51 includes a seed layer and a plating layer, for example. For example, the seed layer may include a titanium (Ti) layer, a nickel (Ni) layer, a nickel-chromium (NiCr) alloy layer, or a tantalum (Ta) layer, and the plating layer may include a gold (Au) layer. The backside electrode 51 is an example of a second metal layer.

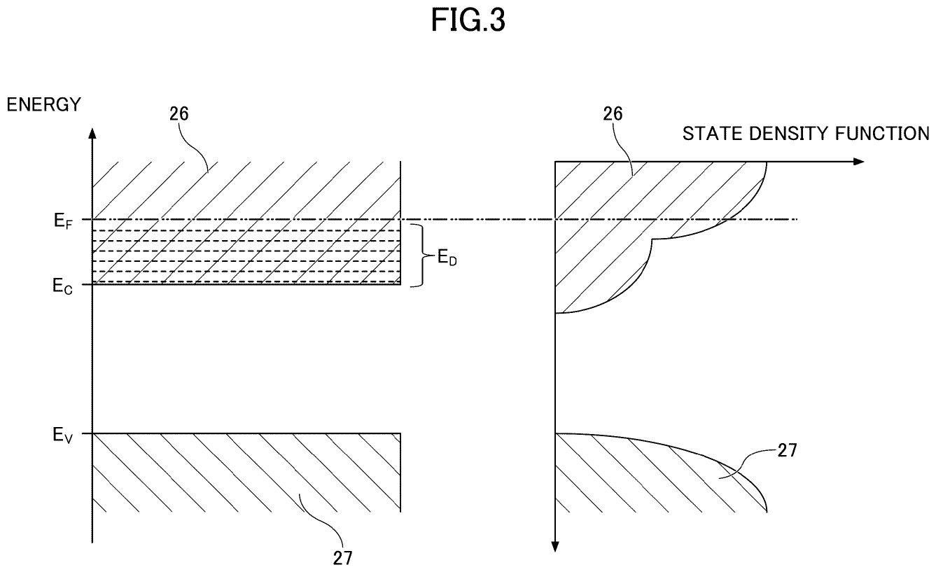

In the semiconductor device 100, the semiconductor layer 21S is formed in the recess 13S of the semiconductor layer 12, and the semiconductor layer 21S includes impurity atoms at a concentration of 1.0×10¹⁸ cm⁻³ or higher. In this semiconductor layer 21S, a distance between the impurity atoms is short, and as illustrated in FIG. 3, a bonding band is formed by the interaction between impurity levels (E_{D}), which connects to a conduction band 26. In this state, because a Fermi level (E_{F}) is present in the conduction band 26, that is, the Fermi level (E_{F}) is higher than an energy (E_{C}) at a lower end of the conduction band 26, the semiconductor layer 21S exhibits characteristics similar characteristics of metals. That is, the semiconductor layer 21S functions as a degenerate semiconductor layer. Accordingly, an ohmic contact is obtained between the semiconductor layer 21S and the source electrode 30S. FIG. 3 is a diagram illustrating a band structure of the semiconductor layer 21S. In FIG. 3, E_{V} indicates an energy at an upper end of a valence band 27.

### First Example of Method for Manufacturing Semiconductor Device

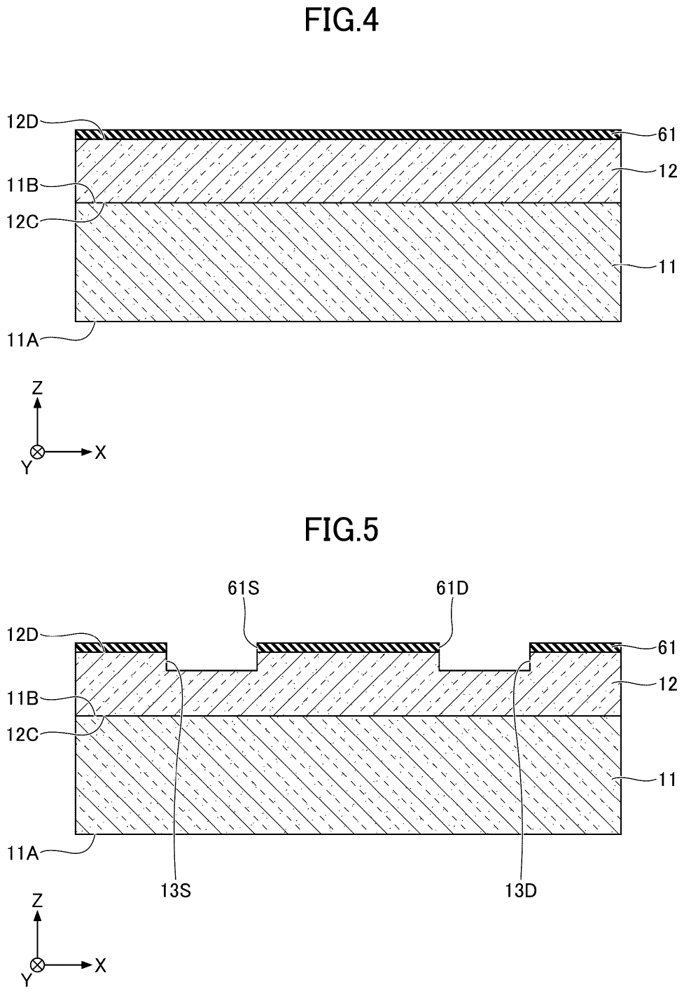

Next, a first example of a method for manufacturing the semiconductor device 100 according to the first embodiment will be described. FIG. 4 through FIG. 14 are cross sectional views illustrating the first example of the method for manufacturing the semiconductor device 100 according to the first embodiment.

In the first example, as illustrated in FIG. 4, the semiconductor layer 12 is formed on the substrate 11 by metal organic chemical vapor deposition (MOCVD), for example. The substrate 11 has the first surface 11A, and the second surface 11A opposite to the first surface 11B. The semiconductor layer 12 has the third surface 12C in contact with the second surface 11B, and the fourth surface 12D is opposite to the third surface 12C. Next, the insulating film 61 is formed on the semiconductor layer 12. The insulating film 61 can be formed by plasma chemical vapor deposition (plasma CVD), for example. The insulating film 61 covers the fourth surface 12D of the semiconductor layer 12.

Next, as illustrated in FIG. 5, the openings 61S and 61D are formed in the insulating film 61, and the recesses 13S and 13D are formed in the insulating film 61. When forming the openings 61S and 61D, reactive ion etching (RIE) of the insulating film 61 is performed using a resist pattern as a mask. for example. When performing the RIE of the insulating film 61, a reactive gas including fluorine (F) is used, for example. When forming the recesses 13S and 13D, RIE of the semiconductor layer 12 is performed using the resist pattern used when forming the openings 61S and 61D as a mask. When performing the RIE of the semiconductor layer 12, a reactive gas including chlorine (Cl) is used, for example.

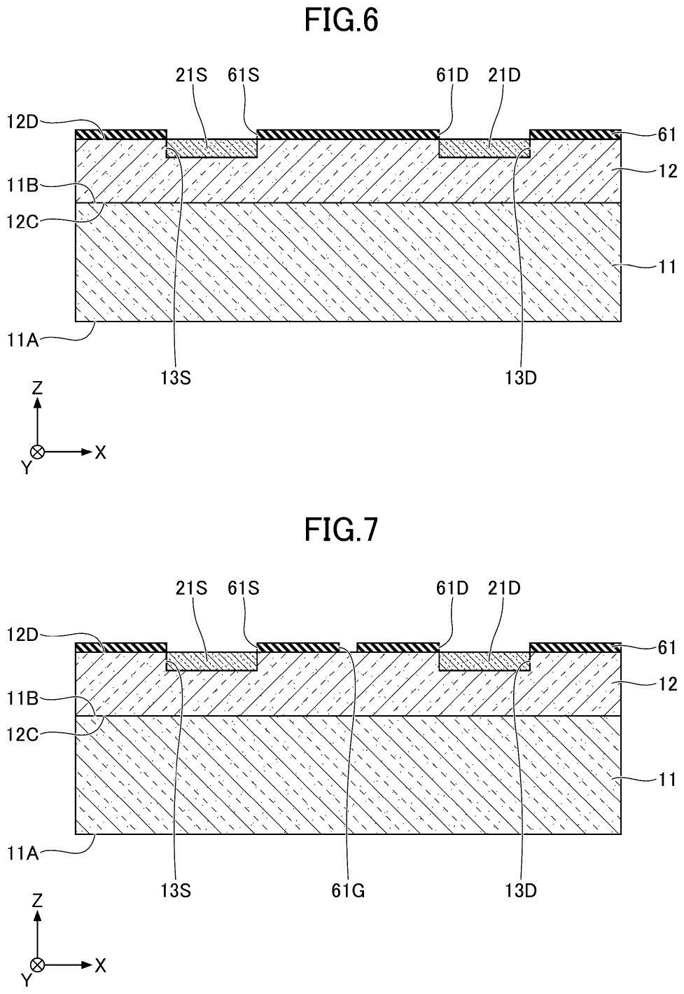

Next, as illustrated in FIG. 6, the semiconductor layer 21S is formed in the recess 13S, and the semiconductor layer 21D is formed on the recess 13D. When forming the semiconductor layers 21S and 21D, crystal growth of the semiconductor layer is performed by MOCVD, molecular beam epitaxy (MBE), or sputtering using a growth mask, and the growth mask is thereafter removed, for example. The semiconductor layers 21S and 21D are the so-called regrowth layers.

Next, as illustrated in FIG. 7, the opening 61G is formed in the insulating film 61. When forming the opening 61G, RIE is performed using a resist pattern as a mask, for example. When performing the RIE of the insulating film 61, a reactive gas including fluorine (F) is used, for example.

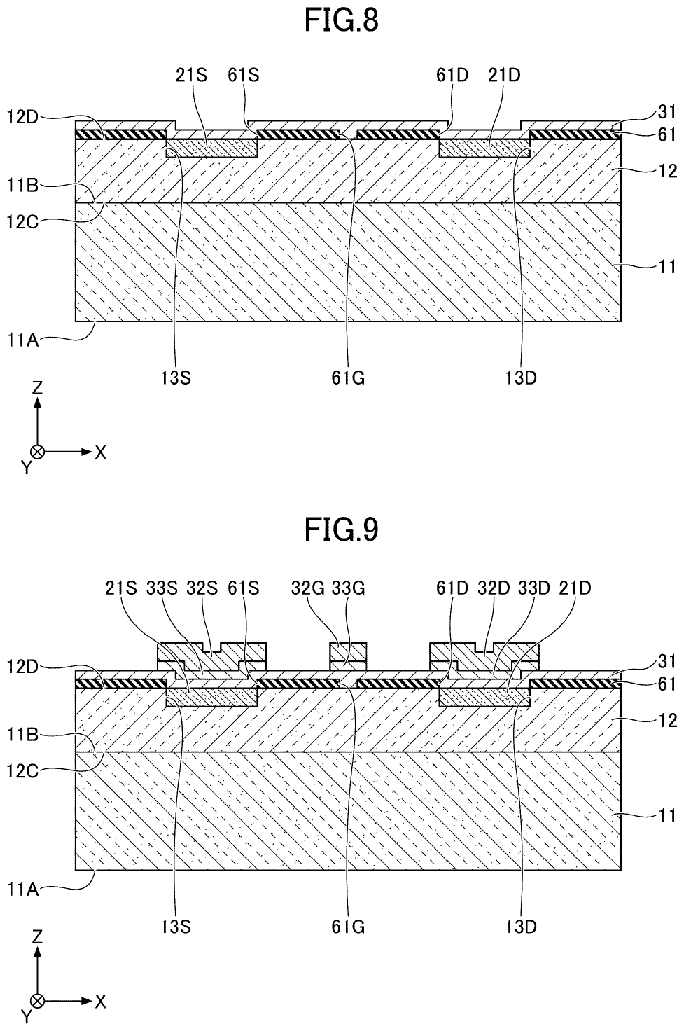

Next, as illustrated in FIG. 8, the metal layer 31 is formed by atomic layer deposition (ALD). The metal layer 31 is formed on the insulating film 61, on the inner wall surfaces of the openings 61S, 61D, and 61G, on the semiconductor layer 21S, on the semiconductor layer 21D, and on a portion of the semiconductor layer 12 exposed through the opening 61G. The metal layer 31 includes cobalt (Co) in an amorphous state. In a case where a Co layer is formed as the metal layer 31, cobalt bisdiisopropylbutanamidinate (Bis (diisopropyl-butanamidinate) cobalt) is supplied as a Co source material into an ALD furnace, for example. In addition, at least one kind of gas selected from a group consisting of hydrogen (H₂) gas and ammonia (NH₃) gas is supplied into the ALD furnace for decomposition of the Co source material. Nitrogen (N₂) gas or argon (Ar) gas, which is an inert gas, may be used as a carrier gas. The metal layer 31 is an example of a fifth metal layer.

When forming the metal layer 31, as illustrated in FIG. 15, a temperature inside the ALD furnace is raised from room temperature to 200° C., and the metal layer 31 is formed at 200° C., for example. After the metal layer 31 is formed, the temperature inside the ALD furnace is lowered to room temperature. FIG. 15 is a diagram illustrating an example of a change in temperature when forming the metal layer 31.

Next, as illustrated in FIG. 9, a stacked body (or a multi-layer structure) of the metal layers 32G and 33G, a stacked body of the metal layers 32S and 33S, and a stacked body of the metal layers 32D and 33D are formed on the metal layer 31. These stacked bodies can be formed by vapor deposition and lift-off, for example.

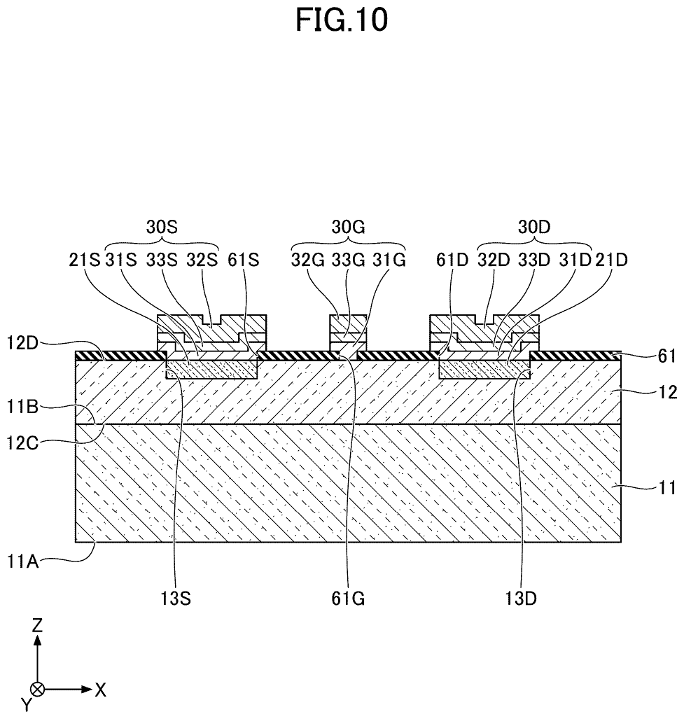

Next, as illustrated in FIG. 10, portions of the metal layer 31 exposed from the stacked bodies described above are removed. That is, the metal layer 31 is patterned. By this patterning, the metal layers 31G, 31S, and 31D are formed from the metal layer 31. The metal layer 31G is in direct contact with the semiconductor layer 12, the metal layer 31S is in direct contact with the semiconductor layer 21S, and the metal layer 31D is in direct contact with the semiconductor layer 21D. Wet etching or milling is performed during this patterning. Next, annealing is performed in a nitrogen gas (N₂) atmosphere at a temperature higher than or equal to 350° C. and lower than or equal to 450° C. for a time longer than or equal to 10 minutes and shorter than or equal to 50 minutes. As a result, the gate electrode 30G including the metal layers 31G, 32G, and 33G, the source electrode 30S including the metal layers 31S, 32S, and 33S, and the drain electrode 30D including the metal layers 31D, 32D, and 33D are formed. Annealing may be performed before the patterning of the metal layer 31.

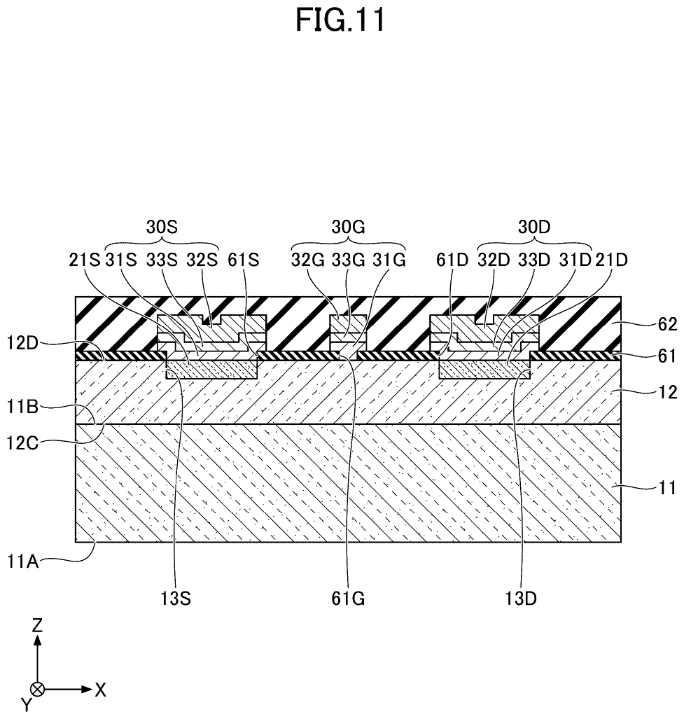

Next, as illustrated in FIG. 11, the insulating film 62 is formed on the source electrode 30S, the drain electrode 30D, the gate electrode 30G, and the insulating film 61. The insulating film 62 can be formed by plasma CVD, for example. The insulating film 62 covers the source electrode 30S, the drain electrode 30D, the gate electrode 30G, and the insulating film 61.

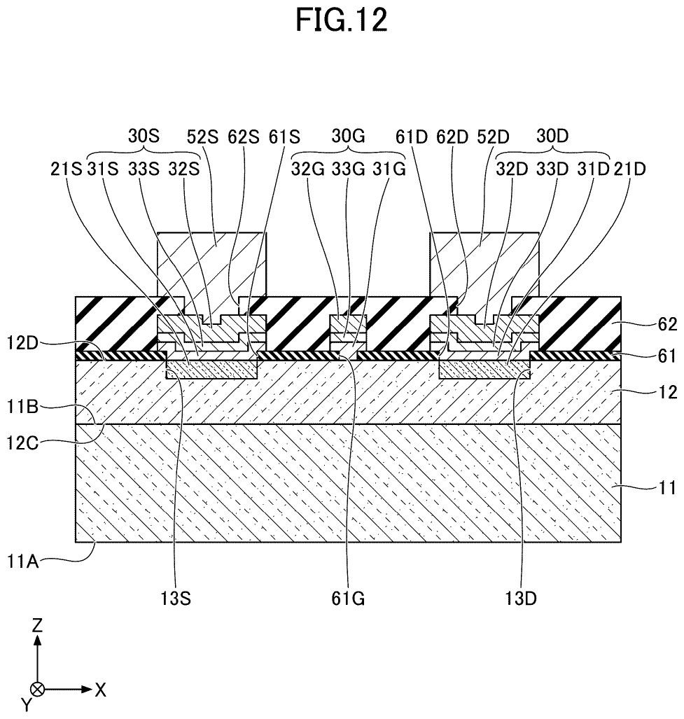

Next, as illustrated in FIG. 12, the openings 62S and 62D are formed in the insulating film 62. When forming the openings 62S and 62D, RIE of the insulating film 62 is performed using a resist pattern as a mask, for example. When performing the RIE of the insulating film 62, a reactive gas including fluorine (F) is used, for example. Next, the source interconnect 52S in contact with the source electrode 30S through the opening 62S, and the drain interconnect 52D in contact with the drain electrode 30D through the opening 62D, are formed on the insulating film 62.

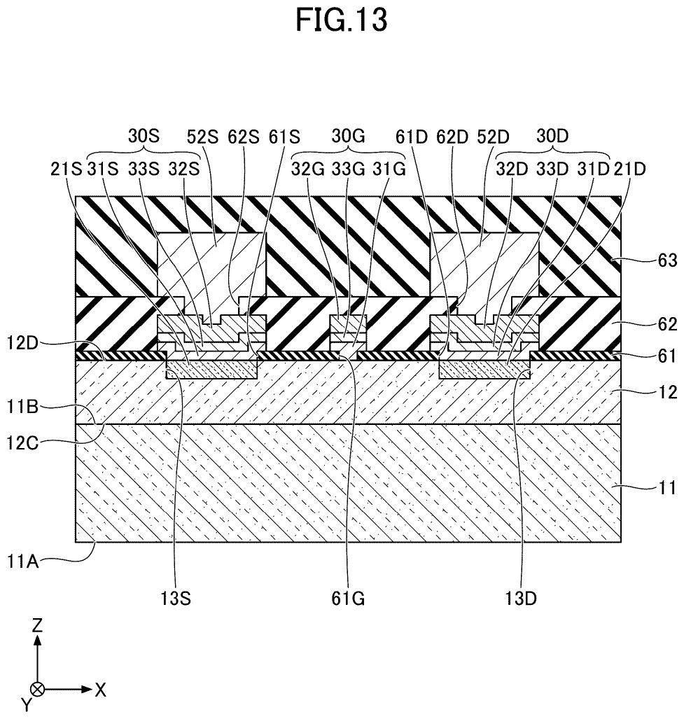

Next, as illustrated in FIG. 13, the insulating film 63 is formed on the insulating film 62. The insulating film 63 can be formed by plasma CVD, for example. The insulating film 63 covers the source interconnect 52S, the drain interconnect 52D, and the insulating film 62.

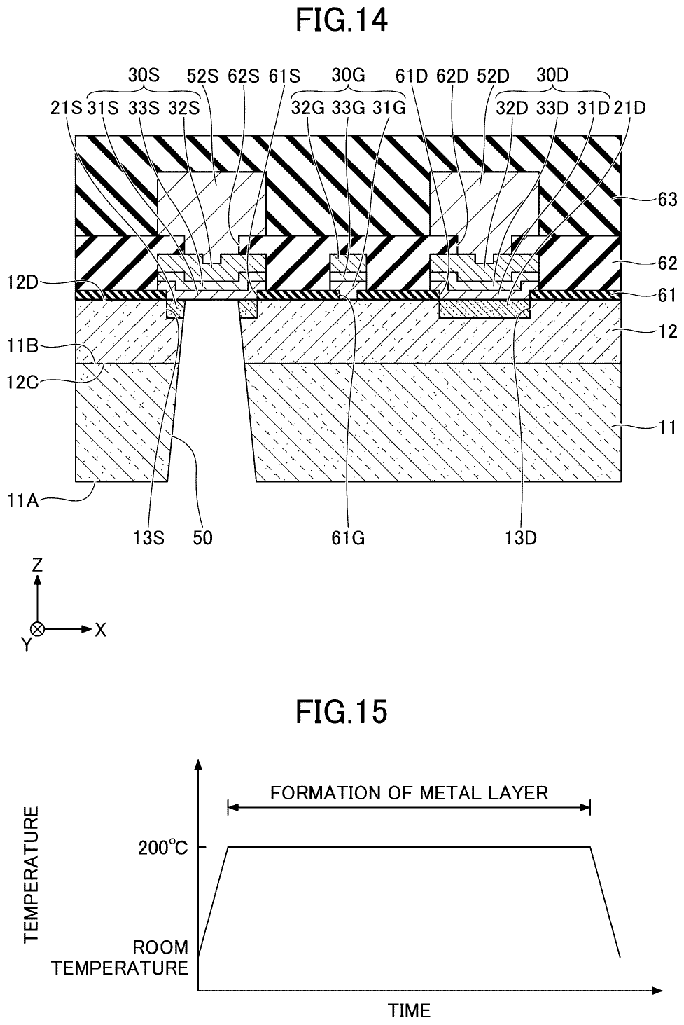

Next, as illustrated in FIG. 14, the through hole 50 is formed in the substrate 11, the semiconductor layer 12, and the semiconductor layer 21S, so as to penetrate the substrate 11, the semiconductor layer 12, and the semiconductor layer 21S. The through hole 50 is formed so as to reach the source electrode 30S. The lower surface of the source electrode 30S is exposed inside the through hole 50. When forming the through hole 50, the substrate 11 is etched, and the semiconductor layers 12 and 21S are etched thereafter. When etching the semiconductor layers 12 and 21S, a reactive gas including chloride (Cl) is used, for example. The metal layer 31S including cobalt (Co) is highly resistant to etching using a reactive gas including chloride (Cl). Accordingly, the metal layer 31S functions as an etching stopper. When etching the substrate 11 to form the through hole 50, a mask is formed on the first surface 11A, and the mask is removed after the etching of the substrate 11. In addition, after the through hole 50 is formed, the inside of the through hole 50 is cleaned.

Next, the backside electrode 51 is formed (refer to FIG. 2). The backside electrode 51 is in contact with the source electrode 30S, and covers the first surface 11A and the inner wall surface of the through hole 50.

The semiconductor device 100 according to the first embodiment can be manufactured by the processes of the first example described above.

### Second Example of Method for Manufacturing Semiconductor Device

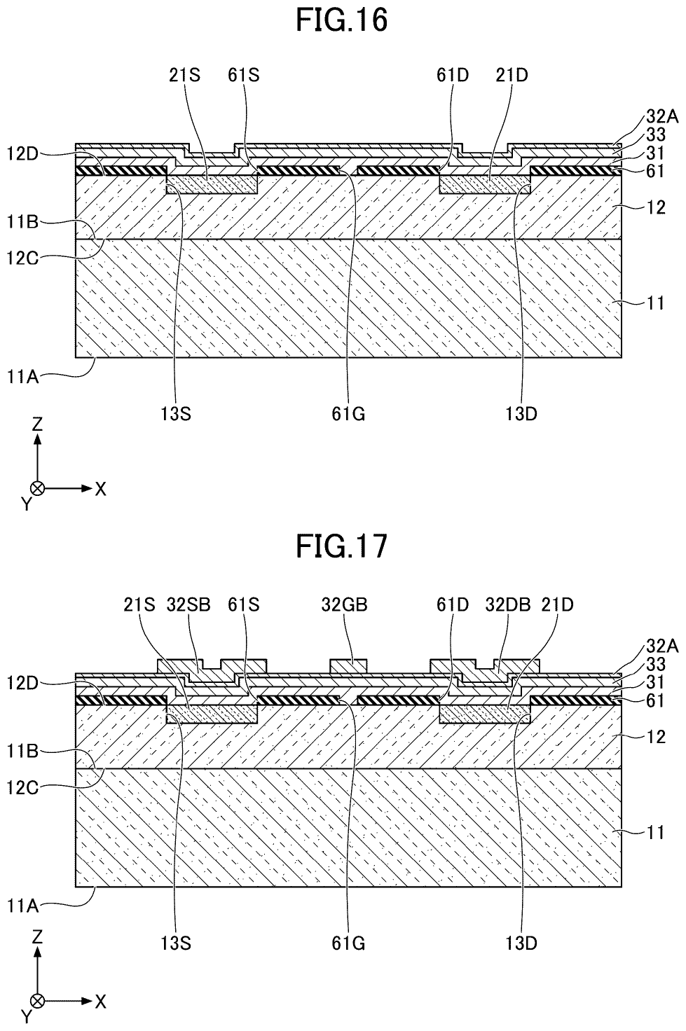

Next, a second example of the method for manufacturing the semiconductor device 100 according to the first embodiment will be described. FIG. 16 through FIG. 18 are cross sectional views illustrating the second example of the method for manufacturing the semiconductor device 100 according to the first embodiment.

In the second example, the processes up to the process of forming the metal layer 31 are performed in the same manner as in the first example (refer to FIG. 4 through FIG. 8). Next, as illustrated in FIG. 16, the metal layer 33 is formed on the metal layer 31, and a metal layer 32A is formed on the metal layer 33. For example, the metal layer 33 is a titanium (Ti) layer, and the metal layer 32A is a gold (Au) layer. The metal layers 33 and 32A are formed by sputtering, for example.

Next, as illustrated in FIG. 17, metal layers 32GB, 32SB, and 32DB are formed on the metal layer 32A. The metal layer 32GB is formed in a region (or area) where the metal layer 32G is to be formed, the metal layer 32SB is formed in a region where the metal layer 32S is to be formed, and the metal layer 32DB is formed in a region where the metal layer 32D is to be formed. Each of the metal layers 32GB, 32SB, and 32DB is formed to a thickness such that a sum of the thickness thereof and the thickness of the metal layer 32A matches the thickness of each of the metal layers 32G, 32S, and 32D, respectively. The metal layers 32GB, 32SB, and 32DB can be formed by plating using the metal layer 32A as a seed layer and a plating resist as a mask.

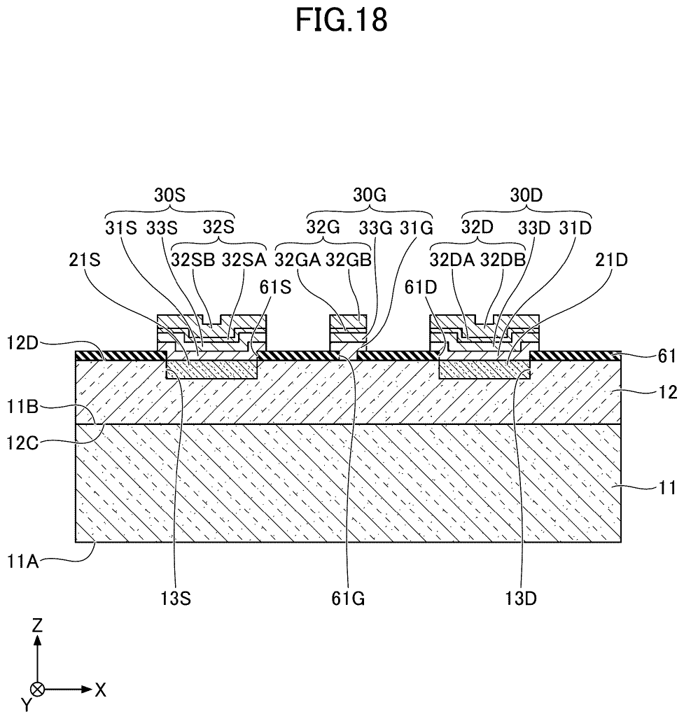

Next, as illustrated in FIG. 18, portions of the metal layers 32A, 33, and 31 exposed from the metal layers 32GB, 32SB, and 32DB are removed. That is, the metal layers 32A, 33, and 31 are patterned. By this patterning, the metal layers 32GA, 32SA, and 32DA are formed from the metal layer 32A, the metal layers 33G, 33S, and 33G are formed from the metal layer 33, and the metal layers 31G, 31S, and 31D are formed from the metal layer 31. The metal layer 31G is in direct contact with the semiconductor layer 12, the metal layer 31S is in direct contact with the semiconductor layer 21S, and the metal layer 31D is in direct contact with the semiconductor layer 21D. Further, the metal layer 32G is obtained from the metal layers 32GA and 32GB, the metal layer 32S is obtained from the metal layers 32SA and 32SB, and the metal layer 32D is obtained from the metal layers 32DA and 32DB. Wet etching or milling is performed during this patterning. Next, annealing is performed in a nitrogen gas (N₂) atmosphere at a temperature higher than or equal to 350° C. and lower than or equal to 450° C. for a time longer than or equal to 10 minutes and shorter than or equal to 50 minutes. As a result, the gate electrode 30G including the metal layers 31G, 32G, and 33G, the source electrode 30S including the metal layers 31S, 32S, and 33S, and the drain electrode 30D including the metal layers 31D, 32D, and 33D are formed. Annealing may be performed before the patterning the metal layers 32A, 33 and 31.

Thereafter, the process of forming the insulating film 62 and the subsequent processes are performed in the same manner as in the first example (refer to FIG. 11 through FIG. 14 and FIG. 2).

The semiconductor device 100 according to the first embodiment can be manufactured by the processes of the second example described above.

In the semiconductor device 100, the backside electrode 51 is in contact with the source electrode 30S, and the source electrode 30S and the semiconductor layer 21S are in ohmic contact with each other. For this reason, the electrical resistance between the semiconductor layer 12 including the 2 DEG and the backside electrode 51 is low. Accordingly, the semiconductor device 100 has a good stability of the electrical resistance between the backside electrode 51 and the semiconductor layer 12, and the yield of the semiconductor device 100 can be improved.

It is also conceivable to use a nickel (Ni) layer as the metal layer 31S, but nickel may react with a material used for removing the mask after etching the substrate 11 and a material used for cleaning the inside of the through hole 50. For this reason, in a case where the nickel (Ni) layer is used as the metal layer 31S, a partial loss of the metal layer 31S may occur, which may increase a contact resistance between the source electrode 30S and the semiconductor layer 21S, and deteriorate the yield of the semiconductor device. In contrast, in the semiconductor device 100, the metal layer 31S includes cobalt (Co), and the metal layer 31S is highly resistant to the material used for removing the mask after etching the substrate 11 and the material used for cleaning the inside of the through hole 50. Accordingly, an increase in the contact resistance as in the case where the nickel (Ni) layer is used does not occur, and the yield of the semiconductor device 100 can be improved.

Because the semiconductor layer 21S is a GaN layer, a low electrical resistance can easily be obtained for the semiconductor layer 21S.

The electrical resistance of the semiconductor device 100 can easily be reduced, by making the carrier concentrations of the semiconductor layers 21S and 21D higher than the carrier concentration of the semiconductor layer 12. In particular, the electrical resistance between the backside electrode 51 and the drain interconnect 52D can easily be reduced.

The semiconductor layer 21S may include n-type impurity atoms at a concentration of 1.0×10¹⁹ cm⁻³ or higher, or may include n-type impurity atoms at a concentration of 1.0×10²⁰ cm⁻³ or higher. The higher the concentration of the n-type impurity atoms included in the semiconductor layer 21S, the easier it becomes to obtain an ohmic contact with the source electrode 30S. Similarly, the semiconductor layer 21D may include n-type impurity atoms at a concentration of 1.0×10¹⁹ cm⁻³ or higher, or may include n-type impurity atoms at a concentration of 1.0×10²⁰ cm⁻³ or higher. The higher the concentration of the n-type impurity atoms included in the semiconductor layer 21D, the easier it becomes to obtain an ohmic contact with the drain electrode 30D. The concentration of the impurity atoms can be measured by secondary ion mass spectrometry (SIMS).

In the semiconductor device 100, the metal layers 31G, 31S, and 31D can be formed simultaneously. Because the metal layer 31G includes cobalt in the amorphous state, the metal layer 31G can make a gate leakage less likely to occur. Hence, according to the semiconductor device 100, the gate leakage can be reduced. Further, because cobalt (Co) has a relatively large work function, a high Schottky barrier can easily be obtained at the gate electrode 30G. In particular, when the surface of the semiconductor layer 12 exposed through the opening 61G is reduced before the metal layer 31 is formed, an even higher Schottky barrier can easily be obtained.

In a case where the metal layer 31G includes hydrogen, carbon, nitrogen, and oxygen, the state of the metal layer 31G can more easily be made amorphous. Ratios of the hydrogen (H) atoms, the carbon (C) atoms, the nitrogen (N) atoms, and the oxygen (O) atoms occupying the metal layer 31G are greater than or equal to 2 atomic percent (at. %) and less than or equal to 25 atomic percent (at. %), for example. The ratio of each of the hydrogen atoms, the carbon atoms, the nitrogen atoms, and the oxygen atoms can be measured by SIMS, respectively. The hydrogen atoms and the nitrogen atoms are derived from the source material of the metal layer 31 and the carrier gas. The carbon atoms and the oxygen atoms are derived from the source material of the metal layer 31.

The thickness of the metal layer 31G is greater than or equal to 3 nm and less than or equal to 50 nm, for example, as described above. When the thickness of the metal layer 31G is less than 3 nm, it may be become difficult to reduce the gate leakage. When the thickness of the metal layer 31G is greater than 50 nm, the electrical resistance of the gate electrode 30G may become too high. The thickness of the metal layer 31G may be greater than or equal to 5 nm and less than or equal to 30 nm, or may be greater than or equal to 7 nm and less than or equal to 20 nm.

The thickness of the metal layer 31G may be measured using a transmission electron microscope (TEM) or a scanning transmission electron microscope (STEM). In the present disclosure, the thickness of the metal layer 31G is a minimum size along the Z-axis perpendicular to the fourth surface 12D of the semiconductor layer 12 inside the opening 61G.

Because the gate electrode 30G includes the metal layer 32G and the electrical resistance of the metal layer 32G is lower than the electrical resistance of the metal layer 31G, the electrical resistance of the gate electrode 30G can be reduced. Because the source electrode 30S includes the metal layer 32S and the electrical resistance of the metal layer 32S is lower than the electrical resistance of the metal layer 31S, the electrical resistance of the source electrode 30S can be reduced. Because the drain electrode 30D includes the metal layer 32D and the electrical resistance of the metal layer 32D is lower than the electrical resistance of the metal layer 31D, the electrical resistance of the drain electrode 30D can be reduced. The metal layers 32G, 32S, and 32D are not limited to gold (Au) layers. The metal layers 32G, 32S, and 32D may include at least one kind of material selected from a group consisting of gold (Au), copper (Cu), and aluminum (Al).

Because the gate electrode 30G has the metal layer 33G between the metal layer 31G and the metal layer 32G, a good adhesion can be obtained between the metal layer 31G and the metal layer 32G. The source electrode 30S has the metal layer 33S between the metal layer 31S and the metal layer 32S, and thus, a good adhesion can be obtained between the metal layer 31S and the metal layer 32S. The drain electrode 30D has the metal layer 33D between the metal layer 31D and the metal layer 32D, and thus, a good adhesion can be obtained between the metal layer 31D and the metal layer 32D. When the metal layers 33G, 33S, and 33D include titanium, a good adhesion can easily be obtained.

Because the metal layer 31 including cobalt is formed by the ALD, the state of the metal layer 31 can more easily be made amorphous. When the source material of the metal layer 31 includes cobalt bisdiisopropyl-butanamidinate, the state of the metal layer 31 can more easily be made amorphous. In addition, when forming the metal layer 31, at least one kind of gas selected from the group consisting of hydrogen (H₂) gas and ammonia (NH₃) gas is supplied into the ALD furnace together with the source material, so that the source material is easily decomposed, and the state of the metal layer 31 is particularly more easily made amorphous. When one of the hydrogen gas and the ammonia gas is supplied to the ALD furnace together with the source material, the other of the hydrogen gas and the ammonia gas does not need to be supplied to the ALD furnace. When at least one of the hydrogen gas and the ammonia gas is supplied to the ALD furnace, the source material can be decomposed.

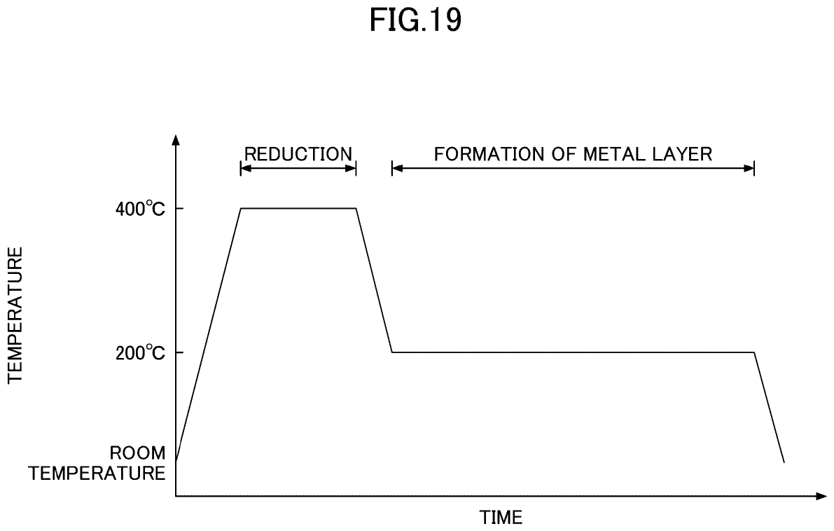

As illustrated in FIG. 19, by performing a reduction process at a first temperature at which a natural oxide film on the surface of the semiconductor layer 12 is decomposed, good Schottky characteristics can be obtained between the gate electrode 30G and the semiconductor layer 12. For example, a high Schottky barrier can be obtained, a high threshold voltage can be obtained for the high electron mobility transistor, and a high voltage can be applied to the gate electrode 30G. For example, the natural oxide film is a gallium oxide (Ga₂O₃) film, and the first temperature is higher than or equal to 400° C. and lower than or equal to 500° C. The metal layer 31 is formed at a second temperature lower than the first temperature. The second temperature is higher than or equal to 150° C. and lower than or equal to 250° C., for example. FIG. 19 is a diagram illustrating another example of the change in temperature when forming the metal layer 31.

For example, hydrogen (H₂) gas and ammonia (NH₃) gas are used for the reduction process. In this case, oxygen atoms are removed from the natural oxide film by the hydrogen gas, and nitrogen defects in the semiconductor layer 12 are compensated for by the ammonia gas. During the reduction process, a flow rate of the H₂ gas is set greater than or equal to 1 standard cubic centimeter (sccm) and less than or equal to 500 sccm, and a flow rate of the NH₃ gas is set greater than or equal to 1 sccm and less than or equal to 500 sccm.

In the case where the reduction process is performed, the reduction process and the formation of the metal layer 31 are performed in the same furnace without being exposed to the atmosphere, that is, the processes are continuously performed in situ, whereby an exceptionally high level of cleanliness is achieved on the surface of the semiconductor layer 12. For this reason, superior Schottky characteristics can easily be obtained. The supply of the hydrogen gas and the ammonia gas can be continued from the reduction process until the formation of the metal layer 31.

In addition, in the case where the reduction process is performed, the reduction process and the formation of the metal layer 31 may be performed in different furnaces without being exposed to the atmosphere. In this case, the temperature inside the furnace in which the reduction process is performed and the temperature inside the furnace in which the metal layer 31 is formed may be controlled independently of each other, and a high throughput can easily be obtained.

The distance between the source electrode 30S and the gate electrode 30G is greater than or equal to 0.5 μm and less than or equal to 2 μm, for example. If the distance between the source electrode 30S and the gate electrode 30G is less than 0.5 μm, a withstand voltage may decrease. If the distance between the source electrode 30S and the gate electrode 30G is greater than 2 μm, a sheet resistance may increase. The distance between the source electrode 30S and the gate electrode 30G may be greater than or equal to 0.5 μm and less than or equal to 1 μm.

### Second Embodiment

A second embodiment will be described. The second embodiment differs from the first embodiment mainly in the configurations of the insulating film, the gate electrode, the source electrode, and the drain electrode.

### Structure of Semiconductor Device

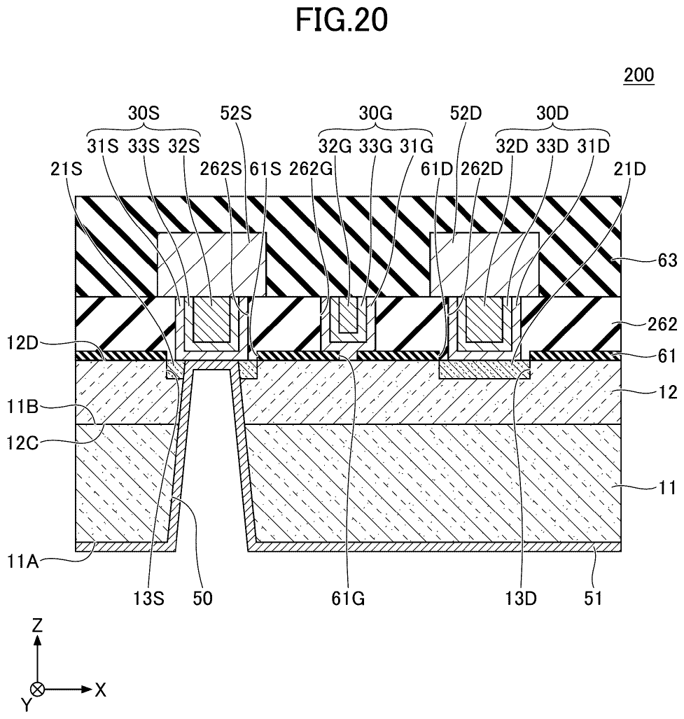

A structure of the semiconductor device according to the second embodiment will be described. FIG. 20 is a cross sectional view illustrating the semiconductor device according to the second embodiment.

As illustrated in FIG. 20, in a semiconductor device 200 according to the second embodiment, an insulating film 262 is provided on the insulating film 61, the semiconductor layer 21S, and the semiconductor layer 21D, in place of the insulating film 62. The insulating film 262 is softer than the insulating film 61. A thickness of the insulating film 262 is greater than or equal to 200 nm and less than or equal to 300 nm, for example. An opening 262G, an opening 262S, and an opening 262D are formed in the insulating film 262. The opening 262G overlaps the opening 61G in a plan view, and extends parallel to the Y-axis. The opening 61G is located inside the opening 262G in the plan view. The opening 262G reaches the insulating film 61. The opening 262S overlaps the opening 61S in the plan view, and extends parallel to the Y-axis. The opening 262S is located inside the opening 61S in the plan view. The opening 262S reaches the semiconductor layer 21S. The opening 262D overlaps the opening 61D in the plan view, and extends parallel to the Y-axis. The opening 262D is located inside the opening 61D in the plan view. The opening 262D reaches the semiconductor layer 21D.

The gate electrode 30G is located inside the opening 61G and the opening 262G. The gate electrode 30G includes the metal layers 31G, 33G, and 32G, similar to the first embodiment. The source electrode 30S is located inside the opening 262S. The source electrode 30S includes the metal layers 31S, 33S, and 32S, similar to the first embodiment. The drain electrode 30D is located inside the opening 262D. The drain electrode 30D includes the metal layers 31D, 33D, and 32D, similar to the first embodiment.

Upper surfaces (+Z-side surfaces) of the insulating film 262, the gate electrode 30G, the source electrode 30S, and the drain electrode 30D coincide with one another. The insulating film 63 is provided on the insulating film 262, the gate electrode 30G, the source electrode 30S, and the drain electrode 30D.

The source interconnect 52S is located above the source electrode 30S. The source interconnect 52S is provided on the source electrode 30S and the insulating film 262. The source interconnect 52S is in contact with the source electrode 30S. The drain interconnect 52D is located above the drain electrode 30D. The drain interconnect 52D is provided on the drain electrode 30D and the insulating film 262. The drain interconnect 52D is in contact with the drain electrode 30D.

The configuration of the semiconductor device 200 is otherwise the same as the configuration of the semiconductor device 100.

### Method for Manufacturing Semiconductor Device

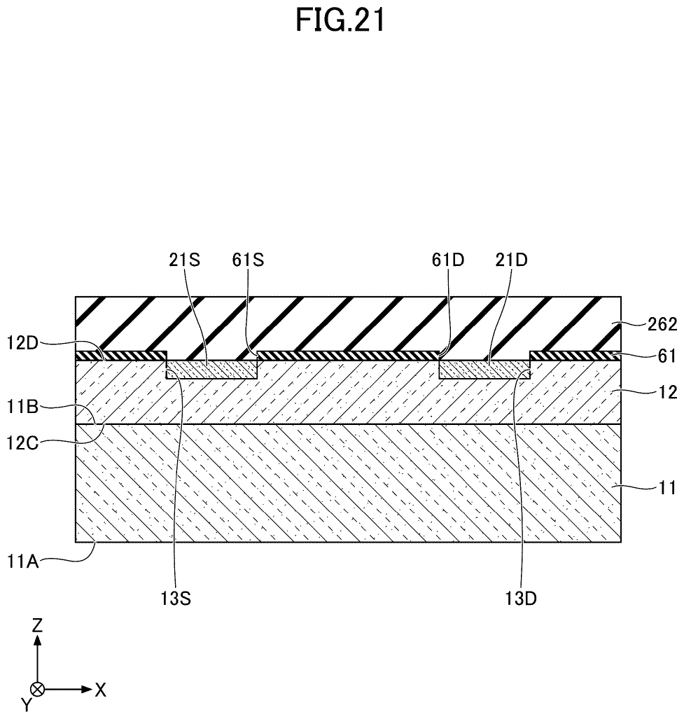

Next, a method for manufacturing the semiconductor device 200 according to the second embodiment will be described. FIG. 21 through FIG. 27 are cross sectional views illustrating the method for manufacturing the semiconductor device 200 according to the second embodiment.

The processes up to the process of forming the semiconductor layers 21S and 21D are performed in the same manner as in the first example of the first embodiment (refer to FIG. 4 through FIG. 6). Next, as illustrated in FIG. 21, then insulating film 262 is formed on the semiconductor layer 21S, the semiconductor layer 21D, and the insulating film 61. The insulating film 262 can be formed by plasma CVD, for example. The insulating film 262 covers the semiconductor layer 21S, the semiconductor layer 21D, and the insulating film 61.

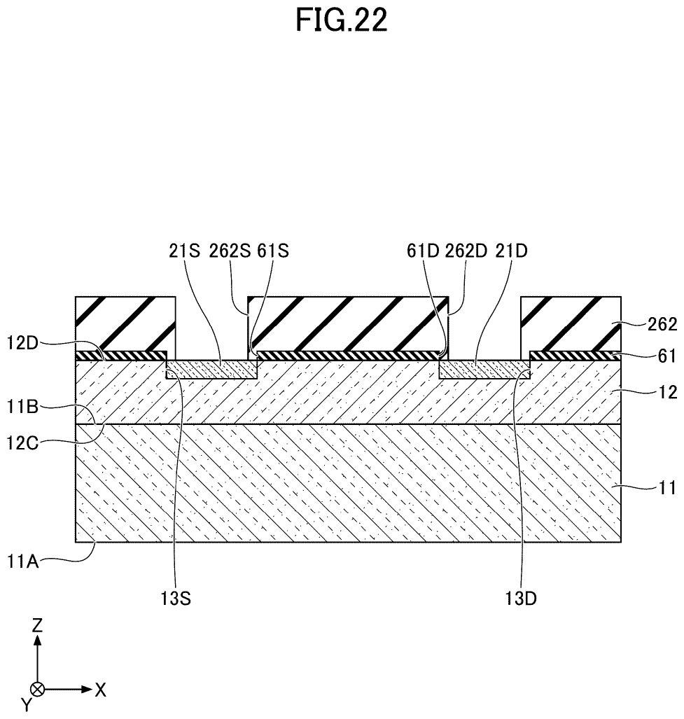

Next, as illustrated in FIG. 22, an opening 262S and an opening 262D are formed in the insulating film 262. When forming the openings 262S and 262D, RIE of the insulating film 262 is performed using a resist pattern as a mask, for example. When performing the RIE of the insulating film 262, a reactive gas including fluorine (F) is used, for example.

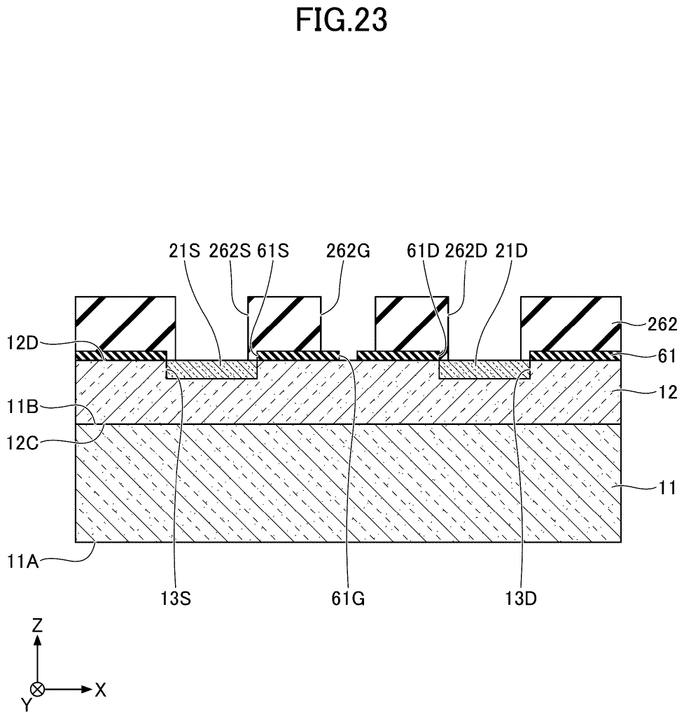

Next, as illustrated in FIG. 23, an opening 262G is formed in the insulating film 262, and an opening 61G is formed in the insulating film 61. When forming the opening 262G and the 61G, RIE of the insulating films 262 and 61 is performed using a resist pattern as a mask, for example. When performing the RIE of the insulating films 262 and 61, a reactive gas including fluorine (F) is used, for example.

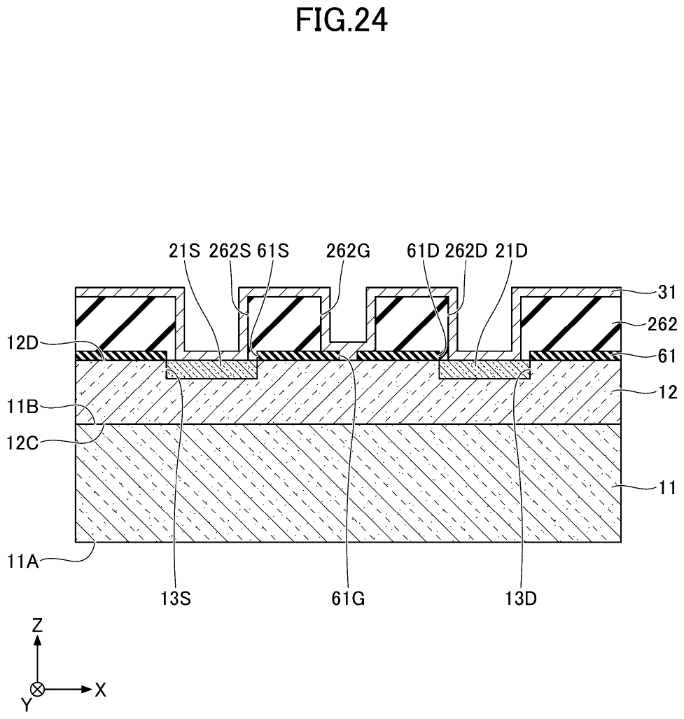

Next, as illustrated in FIG. 24, the metal layer 31 is formed by ALD. The metal layer 31 can be formed under the same conditions as in the first embodiment.

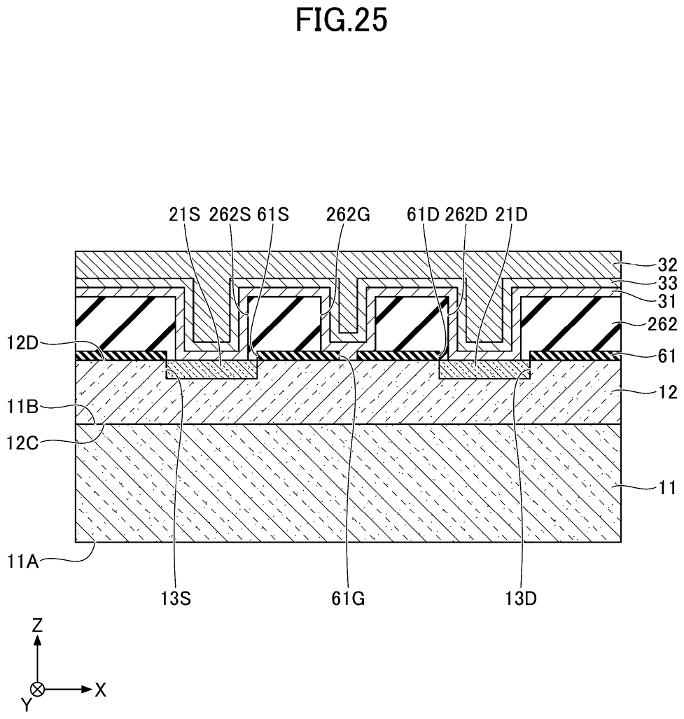

Next, as illustrated in FIG. 25, the metal layer 33 is formed on the metal layer 31, and the metal layer 32 is formed on the metal layer 33. For example, the metal layer 33 is a titanium (Ti) layer, and the metal layer 32 is a gold (Au) layer. The metal layers 33 and 32 are formed by vapor deposition, sputtering, or plating, for example.

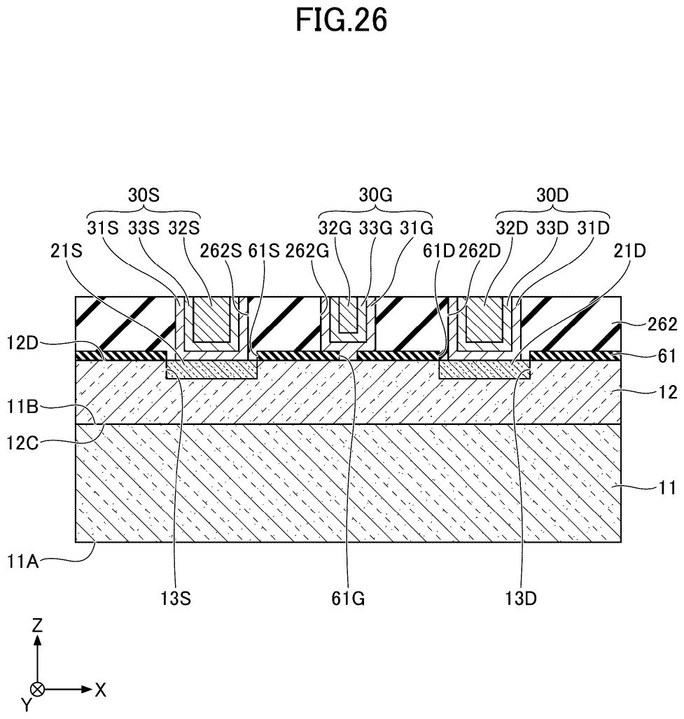

Next, as illustrated in FIG. 26, chemical mechanical polishing (CMP) is performed to make the upper surfaces of the insulating film 262, the metal layer 32, the metal layer 33, and the metal layer 31 coincide with one another. By performing the CMP, the metal layers 32G, 32S, and 32D are formed from the metal layer 32, the metal layers 33G, 33S, and 33D are formed from the metal layer 33, and the metal layers 31G, 31S, and 31D are formed from the metal layer 31. As a result, the gate electrode 30G including the metal layers 31G, 32G, and 33G, the source electrode 30S including the metal layers 31S, 32S, and 33S, and the drain electrode 30D including the metal layers 31D, 32D, and 33D, are formed.

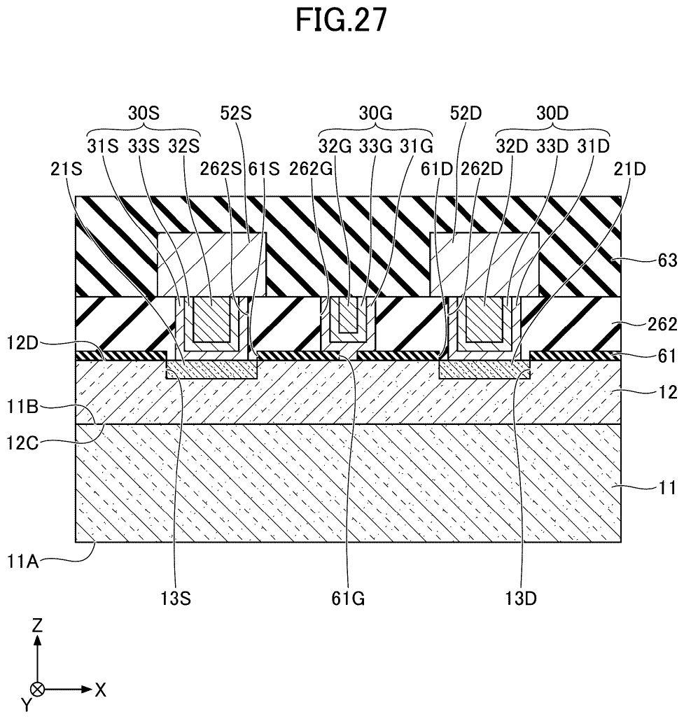

Next, as illustrated in FIG. 27, the source interconnect 52S is formed on the insulating film 262 and the source electrode 30S, and the drain interconnect 52D is formed on the insulating film 262 and the drain electrode 30D. Next, the insulating film 63 is formed on the insulating film 262, the gate electrode 30G, the source interconnect 52S, and the drain interconnect 52D.

Thereafter, the process of forming the through hole 50 and the subsequent processes are performed in the same manner as in the first embodiment (refer to FIG. 14 and FIG. 20).

The semiconductor device 200 according to the second embodiment can be manufactured by the processes described above.

The second embodiment can also improve the yield of the semiconductor device 200, similar to the first embodiment.

The metal layer 31S and the metal layer 31D do not need to be in an amorphous state, and the metal layer 31S and the metal layer 31D may include crystallized cobalt (Co). For example, after the metal layer 31S and the 31D including the crystallized cobalt (Co) are formed, the metal layer 31G including cobalt (Co) in an amorphous state may be formed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a substrate having a first surface, and a second surface opposite to the first surface;
a first nitride semiconductor layer having a third surface in contact with the second surface, and a fourth surface opposite to the third surface, the fourth surface having a recess;
a second nitride semiconductor layer provided inside the recess;
a first metal layer provided on the second nitride semiconductor layer;
a through hole penetrating the substrate, the first nitride semiconductor layer, and the second nitride semiconductor layer, and reaching the first metal layer; and
a second metal layer in contact with the first metal layer and covering the first surface and an inner wall surface of the through hole, wherein:
the first metal layer includes cobalt, and
the second nitride semiconductor layer includes impurity atoms at a concentration of 1.0×10¹⁸ cm⁻³ or higher.

2. The semiconductor device as claimed in claim 1, further comprising:
a third metal layer covering the first metal layer,
wherein an electrical resistance of the third metal layer is lower than an electrical resistance of the first metal layer.

3. The semiconductor device as claimed in claim 2, wherein the third metal layer includes at least one kind of material selected from a group consisting of gold, copper, and aluminum.

4. The semiconductor device as claimed in claim 1, wherein the second nitride semiconductor layer is a gallium nitride layer.

5. The semiconductor device as claimed in claim 1, wherein a Fermi level is higher than energy at a lower end of a conduction band in the second nitride semiconductor layer.

6. The semiconductor device as claimed in claim 1, wherein a carrier concentration of the second nitride semiconductor layer is higher than a carrier concentration of the first nitride semiconductor layer.

7. The semiconductor device as claimed in claim 1, further comprising:
a gate electrode in Schottky contact with the first nitride semiconductor layer, wherein:
the gate electrode includes a fourth metal layer in direct contact with the first nitride semiconductor layer, and
the fourth metal layer includes cobalt.

8. The semiconductor device as claimed in claim 7, wherein the fourth metal layer includes cobalt in an amorphous state.

9. The semiconductor device as claimed in claim 8, wherein the fourth metal layer includes hydrogen atoms, carbon atoms, nitrogen atoms, and oxygen atoms.

10. A method for manufacturing a semiconductor device comprising:
forming a first nitride semiconductor layer on a substrate having a first surface and a second surface opposite to the first surface, the first nitride semiconductor layer having a third surface in contact with the second surface and a fourth surface opposite to the third surface;
forming a recess in the fourth surface;
forming a second nitride semiconductor layer inside the recess;
forming a first metal layer on the second nitride semiconductor layer;
forming a through hole penetrating the substrate, the first nitride semiconductor layer, and the second nitride semiconductor layer and reaching the first metal layer; and
forming a second metal layer in contact with the first metal layer and covering the first surface and an inner wall surface of the through hole, wherein:
the first metal layer includes cobalt, and
the second nitride semiconductor layer includes impurity atoms at a concentration of 1.0×10¹⁸ cm⁻³ or higher.

11. The method for manufacturing the semiconductor device as claimed in claim 10, wherein the forming the first metal layer includes:
forming a fifth metal layer including cobalt in an amorphous state on the first nitride semiconductor layer and the second nitride semiconductor layer by an atomic layer deposition; and
patterning the fifth metal layer,
wherein the patterning the fifth metal layer includes forming a fourth metal layer in direct contact with the first nitride semiconductor layer.

12. The method for manufacturing the semiconductor device as claimed in claim 11, wherein a source material of the fifth metal layer includes cobalt bisdiisopropylbutanamidinate.

13. The method for manufacturing the semiconductor device as claimed in claim 12, wherein the forming the fifth metal layer includes supplying at least one kind of gas selected from a group consisting of hydrogen gas and ammonia gas into a furnace together with the source material.

14. The method for manufacturing the semiconductor device as claimed in claim 11, further comprising:
performing a reduction process at a first temperature at which a natural oxide film on a surface of the first nitride semiconductor layer is decomposed, before the forming the fifth metal layer,
wherein the fifth metal layer is formed at a second temperature lower than the first temperature.

15. The method for manufacturing the semiconductor device as claimed in claim 14, wherein the performing the reduction process and the forming the fifth metal layer are performed in the same furnace without being exposed to atmosphere.

16. The method for manufacturing the semiconductor device as claimed in claim 14, wherein the performing the reduction process and the forming the fifth metal layer are performed in different furnaces without being exposed to atmosphere.

17. The method for manufacturing the semiconductor device as claimed in claim 14, wherein the performing the reduction process uses hydrogen gas and ammonia gas.
